(19) United States
(12) Patent Application Publication
(10) Pub. No.: US 2008/0143355 A1
(43) Pub. Date: Jun. 19, 2008

(54) Method and System for Testing or Measuring Electrical Elements

(75) Inventor: Gerard DELABOUGLISE, Echirolles (FR)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: BEAMIND, Bandol (FR)

(21) Appl. No.: 11/831,218

(22) Filed: Jul. 31, 2007

Related U.S. Application Data
(63) Continuation of application No. PCT/FR06/00153, filed on Jan. 24, 2006.

(30) Foreign Application Priority Data
Feb. 4, 2005 (FR) 0501102

(51) Int. Cl. G01R 31/308

(52) U.S. Cl. 324/752; 29/593

(57) ABSTRACT

A method for testing or measuring electric elements, includes applying a beam of particles to a location of an electric element. Charges are liberated under the effect of the application of the beam of particles. The liberated charges are collected by a collector. The collected quantity of charges is measured, and an electric feature is deduced from the measure of the collected quantity of charges.

### CROSS-REFERENCE TO RELATED APPLICATIONS

This application is a continuation of International Application No. PCT/FR2006/000153 filed Jan. 24, 2006, which was published in the French language on Aug. 10, 2006, under International Publication No. WO 2006/082292, the disclosure of which is incorporated herein by reference.

### BACKGROUND OF THE INVENTION

The invention relates to a method for testing or measuring electric elements, and to a corresponding system.

Electric components, like semiconductor or integrated circuit (IC) chips, and printed circuits are subjected, before being marketed, to testing steps that are an integral part of their manufacturing process. Among the tests conducted, some tests make it possible to determine the continuity and insulation of conducting paths. Other tests make it possible to evaluate the resistance of conducting paths.

U.S. Pat. No. 6,369,591 B1 (Cugini et al.) describes a contactless method for testing the conducting paths of an insulating substrate, using a laser beam. This method only allows the continuity of the conducting paths to be determined and does not give a measure of the resistance and/or the capacitance of these paths. The same applies to the testing method described in the European Patent No. 1 233 275 A2 (Nihon Densan Read K.K.). The Nihon application suggests various methods for determining the continuity of the paths according to whether they are crossing or not (i.e., they pass through the substrate or not). However, these various methods do not make it possible to take a measure of the resistance or the capacitance of conducting paths, i.e., a measure for obtaining a value of the resistance or of the capacitance. The continuity of the crossing paths is measured in the following way: electrons are extracted from a first end of a path by photoelectric effect, the electrons being collected by a collector taken to a unique potential, and the intensity of the current flowing through a circuit linking this collector to the second end of the path is then measured. This current intensity is compared to the known current intensity which would have been obtained with a corresponding path of a substrate without faults (“golden board”) and the continuity or discontinuity of the crossing path is deduced from this comparison. The continuity of the non-crossing paths is measured according to two methods. In both methods, the path to be tested is capacitively coupled to a board located on the opposite side of the substrate. According to a first method, electrons are extracted from one end of the path by photoelectric effect, a current is then generated between the path and the board via the collector, and the intensity of this current is measured and integrated to obtain a value that is compared to the value previously obtained with a golden board. According to a second method, the same process is applied, an intensity of the charging current of the capacitance formed between the path and the board is measured, but by performing two laser shots extracting charges from each end of a conducting path by photoelectric effect. Here again, the results obtained are compared with the known results obtained using a golden board.

European Patent No. 1 236 052 B1 (Vaucher Christophe) describes a testing method allowing the resistance of a conducting path of an insulating substrate to be measured. According to this method, a board with several conducting areas susceptible of being individually taken to any adjustable electric potential is arranged facing the conductor to be tested and near it. A beam of particles is then applied, a laser beam in particular, to a first point of the conductor in order to extract electrons by photoelectric effect. In parallel, electrons are injected into a second point of the conductor, thus causing electric current to flow through this conductor. The current intensity between the two points is then measured and the resistance of the conductor is deduced therefrom, by applying Ohm's law: U=R×I.

However, the implementation of this method proves to be complex. Indeed, the pulse durations of the lasers used are commonly about a few nanoseconds (ns). Consequently, measuring a current I=U/R on such a duration requires an electronic operating at a few gigahertz (GHz), which is very expensive. In addition, operating at these high frequencies implies difficulties linked to the self-inductance of the circuits being tested, which are a nuisance for the measure.

Furthermore, US Patent Application Publication No. 2005/0017729 describes a continuity and insulation test method which is based on a measure of current in most of the configurations described. In the embodiment represented in FIGS. 8 to 14B of this published application, a conducting metal plate 241 is arranged on the rear face of an interconnection support to be tested 211 through an insulant 242 and is taken to a negative potential compared to the collector. Thus, the conductors are electrically biased via a capacitance. A current detector 280 is arranged between the negative potential of the voltage source 270 and the metal plate 210. This current detector comprises an analog-to-digital (A/D) converter the digital output of which is read by a controller 201 which measures an electric charge by integration of the current measured. The detection of an open circuit or the detection of a short-circuit are based on an observation of the quantities of charges measured, required by the fact that the conductors are biased through capacitances created between the metal plate and the rear pads of the interconnection support. No value of an electric feature is measured.

### BRIEF SUMMARY OF THE INVENTION

Given the state-of-the-art, the embodiments of the present invention are directed to a method for testing or measuring electric elements, and a system implementing this method, which do not require the direct measure of a current intensity between two test points and which consequently do not require an electronic operating at a few GHz, implying difficulties linked to the self-inductance of the circuits being tested, which are a nuisance for the measure while also being very expensive.

Embodiments of the present invention provide a method for testing or measuring electric elements, wherein a beam of particles is applied to a first location of an electric element. Electric charges are liberated under the effect of the application of the beam of particles. The liberated electric charges are collected by a collector. The collected quantity of electric charges is measured, and an electric feature of the electric element is deduced from the measure of the collected quantity of electric charges.

According to one embodiment, the beam of particles is a laser beam.

According to one embodiment, the electric element is a conducting path either integrated to or deposited on an insulating substrate and comprises, at each of its two ends, a metallic pad.

According to one embodiment, the first location is a metallic pad.

According to one embodiment, the metallic pad is of C4 type.

Advantageously, the measure of the collected quantity of charges is ensured by a device for measuring collected charges comprising a capacitance, and the measure of the collected quantity of charges is made by measuring the charge of this capacitance.

According to one embodiment, a reset unit synchronizes the measure of the collected quantity of charges at the pulse of the beam of particles.

According to one embodiment, charges are injected into a second location of the electric element so as to compensate for the loss of charges extracted under the action of the beam of particles, and the quantity of charges injected by means of a device for measuring injected charges is measured.

According to one embodiment, the capacitance of the electric element is deduced from the quantity of injected charges.

According to one embodiment, the electric feature is the electric resistance or capacitance of the electric element.

According to one embodiment, the electric feature is the electric continuity of the electric element or the electric insulation of the electric element in relation to another electric element.

Embodiments of the present invention also relate to a method for manufacturing an interconnection support or an electronic circuit arranged on an interconnection support, the interconnection support or the electronic circuit comprising electric elements. The method includes testing or measuring all or part of the electric elements of the interconnection support or of the electronic circuit implemented in accordance with the testing or measuring method according to the invention.

Embodiments of the present invention also relate to a system for testing or measuring electric elements. The system includes a device for generating a beam of particles applied to a first location of an electric element. The application of the beam to the first location causes the liberation of electric charges. The system includes a collector of the liberated electric charges, a device for measuring the collected quantity of electric charges, and a device for deducing, from the measure of the collected quantity of electric charges, an electric feature of the electric element.

According to one embodiment, the system comprises a device for generating a pulse preceding the start of the shot of the beam of particles. The pulse forms an input of a reset unit of the device for measuring the quantity of charges collected by the collector.

According to one embodiment, the system comprises a source allotted to an injection of charges into a second location of the electric element in order to compensate for the loss of charges extracted under the action of the beam of particles.

According to one embodiment, the system comprises a device for measuring the quantity of injected charges.

According to one embodiment, the system comprises a capacitance and measuring the collected quantity of charges is performed by measuring the charge of the capacitance.

According to one embodiment, the system is arranged for deducing an electric feature which is the electric resistance or the electric capacitance of the electric element.

According to one embodiment, the system is arranged for deducing an electric feature which is the electric continuity of the electric element or the electric insulation of the element compared to another electric element.

According to the invention, the collected quantity of charges mainly varies with two parameters, which are the resistance and the capacitance of the electric element. If the value of the capacitance or of the resistance of the element is known, or if it is possible to ignore one of these two parameters, for example by taking double measures or by having a good approximation of one of them from design data of the electric element to be tested, the collected quantity of charges during the application of the beam of particles only varies with this resistance and/or this capacitance, that is the electric feature which measure is wanted. It is therefore not necessary to measure the resistance of the electric element from a current intensity flowing through the element, as it is the case in the aforementioned European Patent No. 1 236 052 B1. The measuring electronic is thus significantly simplified. The electronic is likely to operate according to passbands of about a few kilohertz (kHz), that is according to passbands about six times lower than the operating passband of a measuring electronic operating by measuring the intensity of the current flowing through conducting paths, as in the state-of-the-art.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1A schematically shows an embodiment of a system according to the invention, for measuring the resistance and/or the capacitance of a conducting path of C4-BGA type crossing a substrate;

FIG. 1B schematically shows an embodiment of a system according to the invention, for measuring the resistance and/or the capacitance of a non-crossing conducting path of C4-C4 type;

FIG. 2 is an electrical diagram of the whole formed by the conducting path and the collector, in a system according to the invention;

FIGS. 3A and 3B illustrate the evolution of the voltage of a metallic pad during and after a laser shot and the evolution of the collected charge, according to time, for different values of resistances of the path and a first value of the capacitance of the path;

FIGS. 4A and 4B illustrate the evolution of the voltage of a metallic pad during and after a laser shot and the evolution of the collected charge, according to time, for different values of resistances of the path and a second value of the capacitance of the path;

FIGS. 5A and 5B illustrate the evolution of the voltage of a metallic pad during and after a laser shot and the evolution of the collected charge, according to time, for different values of resistances of the path and a third value of the capacitance of the path;

FIG. 6 illustrates the variation of the charge collected by a collector of a system according to the invention, according to the resistance of the path, for different values of capacitance of the path;

FIG. 7 is a functional diagram of the measuring system according to an embodiment of the invention;

FIG. 8A is a functional diagram of a particular embodiment of the reset unit of the system according to the invention;

FIG. 8B illustrates the different signals generated by a particular embodiment of the reset unit of the system according to the invention;

FIG. 9 is a functional diagram of a particular embodiment of the measuring device of the system according to the invention, located on the ground side; and

FIG. 10 is a functional diagram of an embodiment of the measuring device of the system according to the invention, located on the collector side.

### DETAILED DESCRIPTION OF THE INVENTION

The method and the system according to embodiments of the invention are used to test electric elements like active or passive components, discrete or integrated to a substrate such as printed circuit semiconductor chip or electronic circuit on vitreous substrate used to make flat screens.

The method and the system according to embodiments of the invention also allow an electric feature of the tested electric element to be determined, particularly the electric continuity, the electric resistance or the electric capacitance of the electric element of the test, or the electric insulation of the element in relation to another element or to a group of other elements linked between them. The electric element is for example a conducting path integrated to or deposited on an insulating substrate and fitted, at each of its ends, with a metallic pad either plane or of any other geometrical shape. The insulating substrate is for example a substrate of very high density printed circuit, or HDI printed circuit (High Density Interconnect) which is used in the majority of portable electronic devices like cell phones, MP3 players, CD or DVD readers or digital cameras, and in the composition of packages for semi-conductor chips like microprocessors or memories, the corresponding printed circuits being called “IC package substrates” or “chip carriers”. These substrates comprise a high density of printed metallic conducting paths, these paths sometimes being of a width inferior to a few tens of microns or micrometers (elm) and the pitches between two paths, half less, the metallic paths accessible to the test having dimensions inferior to 100 μm. However, embodiments of the invention also apply to any types of substrates having conducting paths arranged on one or more stages like the substrates forming LCD or plasma flat screens, as well as semi-conductor chips before encapsulation. In addition, the invention further applies to the test of cards equipped with components, called in situ test, to the test of continuity and insulation and to the test of values of passive components like resistances or capacitances.

In practice, measuring the resistance and/or the capacitance of the conducting paths of an insulating substrate aims at checking, the continuity and insulation of the paths in particular, with the view of testing the interconnection network formed by all the conducting paths possibly arranged on several insulating layers of the substrate, and linked by metallized holes or vias.

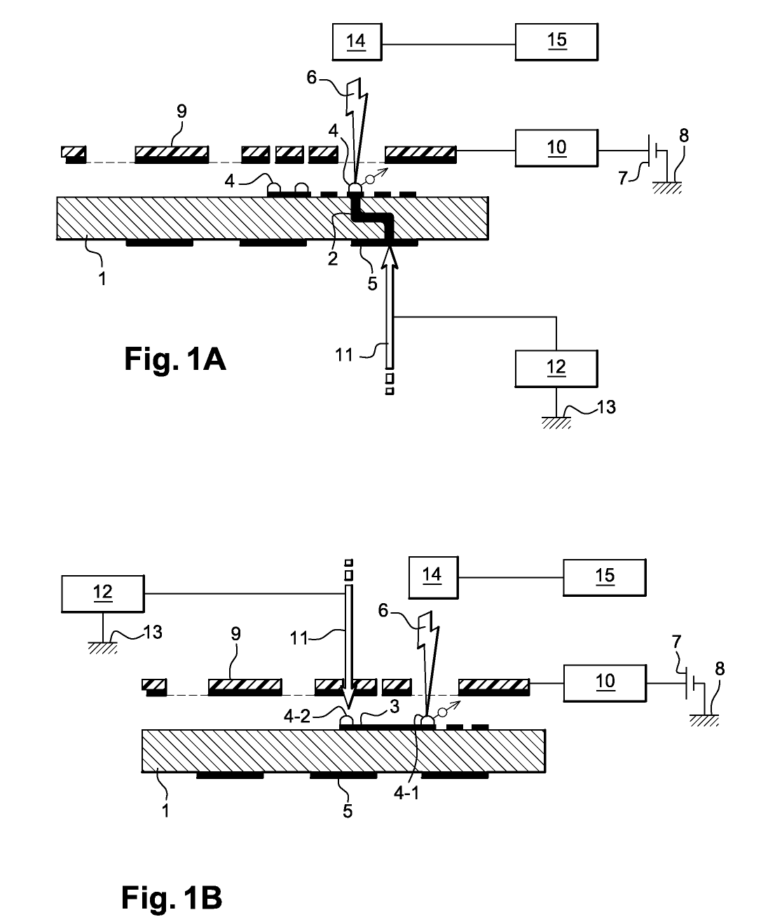

In the example of FIGS. 1A and 1B, the substrate 1 of the test is a chip carrier of spark gap type, which is intended to bring to one pitch of standard printed circuit, about one millimeter between points, an electronic component of semi-conductor chip type having a much higher connection density. The conducting paths 2, 3 of the substrate 1 are located on its surface (path 3), on its upper face or its lower face, or are crossing it (path 2) and link both faces of the substrate. Each end of a conducting path comprises a metallic pad. The metallic pads are located on the upper (pads 4, 4-1, 4-2) and lower (pad 5) faces of the substrate 1. The pads located on the upper face of the substrate particularly allow the chip to be mounted using the flip-chip technique. The pads are for example of C4 type meaning “Controlled Collapsed Chip Connection.” In that case, they are made in a metallic alloy of lead—stain type or an equivalent lead-free alloy. The pads 5 located on the lower face of the substrate are of BGA type meaning “Ball Grid Array.” The metallic pads of C4 type and the metallic pads of BGA type form interconnection contacts arranged under matrix form on the surface of the substrate 1.

The conducting paths being subjected to the measure of resistance according to the invention are either non-crossing paths of C4-C4 type, linking two metallic pads of C4 type on the upper face of the substrate, or non-crossing paths of BGA-BGA type, linking two pads of BGA type on the lower face of the substrate, or crossing paths of C4-BGA type, linking a C4 metallic pad on the upper face of the substrate to a BGA pad on the lower face of the substrate or, more generally, any other types of crossing paths.

According to one particular embodiment of the invention shown in FIG. 1A, a beam of particles 6 is applied to a location of a crossing conducting path 2, the location being formed by a pad 4 of C4 type constituting the end of the path which continuity, resistance and/or capacitance measure is desired. This beam of particles is for example a laser beam 6 supplied by a pulsed laser of YAG type, multiplied in frequency by a factor of five, which pulse duration is preferably about a few ns. The laser energy is measured using a calorimeter 14 linked to a device 15 for measuring the laser energy.

A horizontal board is positioned on the path of the laser beam 6, near the substrate 1, substantially parallel to this substrate 1. This board is taken to a positive voltage Vc, using a generator 7 put to the ground 8. Thus, the board constitutes a collector 9 able to collect the electrons liberated by the conducting paths, when the latter are subjected to the laser beam 6. This collector 9 is linked, according to the invention, to a first device 10 for measuring the collected charge, which is described below, in the present description according to the invention.

To measure the resistance and/or the capacitance of the crossing path 2, the metallic pad 5, located at the other end of the path 2, is linked to an infinite source of electrons 11. This source is located under the lower metallic pad 5 of the path 2, on the lower face of the substrate 1. It can be formed of a wiring board fitted with an addressing electronic, an anisotropic conductive elastomer, a microtip cathode, a carbon nanotube cathode or a second laser beam producing an inverse photoelectric effect. It is linked, according to the invention, to a second measuring device 12 and to the ground 13. Like the first measuring device 10, the second measuring device 12 will be described in further detail below, in the present description according to the invention.

When the beam 6, of short wavelength, in practice in the ultraviolet field, reaches the pad 4, electrons are liberated by the pad, by photoelectric effect. These electrons are collected by the collector 9.

Under the action of the beam of particles 6, an electric current flows through the dipole formed by the metallic pad 4 and the collector 9. This current depends on the energy of the beam of particles and the voltage of the collector 9 according to a law I(V) depending on the pad geometry and on the possible presence of a space charge.

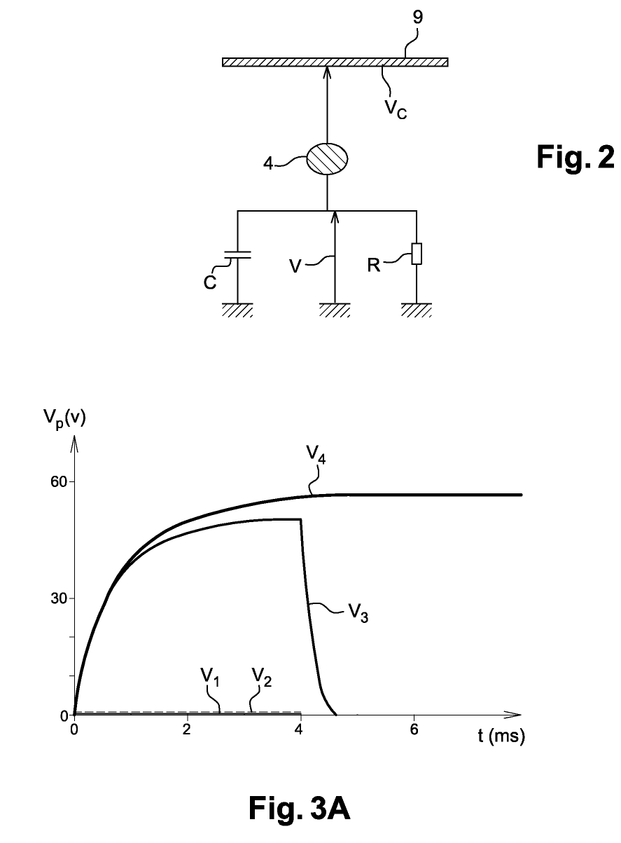

FIG. 2 shows the equivalent electric circuit constituted by the whole formed by the conducting path 2 dotted with the pad 4 and the collector 9 taken to a positive voltage Vc. The conducting path 2 can be modeled by a capacitance C and resistance R circuit, subjected to a voltage V. It is assumed to be put to the ground by the source of electrons 11. In the case of a plane metallic pad and in presence of a space charge, the current flowing between the metallic pad 4 and the collector 9 obeys the Langmuir law and complies with the following equation:

I(V)=kV^{3/2}

which is given for information only, given that it is a characteristic of the dipole in question since it is specific to the geometry of this dipole and to the geometry of the beam 6.

A numerical simulation is performed on the basis of this particular electric circuit. This circuit complies with the following relationships:

$$I = {K ( {V}_{c} - V )}^{3 / 2}$$

$$K = \frac{4 {ɛ}_{0}}{9} * {[ \frac{2 e}{m} ]}^{1 / 2} * \frac{π {D}^{2}}{4 {d}^{2}}$$

$$\frac{δ V}{δ t} = \frac{K}{C} {( {V}_{c} - V )}^{3 / 2} - \frac{V}{RC}$$

$${V}_{t + Δ t} = {V}_{t} + Δ t * {( \frac{K}{C} {( {V}_{c} - V )}^{3 / 2} - \frac{V}{RC} )}_{t}$$

The parameters used in the simulation are described in the following Table 1.

TABLE 1

| | |
|---|---|
| m (mass of the electron) | 9 × 10⁻³¹ kilograms (kg) |
| q (charge of the electron) | 1.6 × 10⁻¹⁹ Coulombs (c) |
| ε₀ (permittivity of free space) | 8.84643 × 10⁻¹² Farads (f)/meter (m) |
| Vc (voltage of the collector) | 60 Volts (V) |
| d (distance between pad/collector) | 100 μm |
| D (laser beam diameter) | 100 μm |
| J_{diode} (current density between the | 1.6 × 10⁵ Amperes (a)/m² |
| pad and the collector) | |
| I_{diode} (charges which can be | 1.28 milliamperes (mA) |
| collected during the pulse, the | |
| metallic pad being put to | |
| the ground) | |
| Velocity of light | 300,000 Kilometers (km)/second (s) |
| E (laser) | 10 microJoules (μJ) |
| DI (pulse duration) | 4 ns |
| δ (photoelectric yield) | 1.00 × 10⁻⁵ |
| h (Planck's constant) | 6.63 × 10⁻³⁴ Joules (J)/s |
| λ (photons wavelength) | 213 nanometer (nm) |
| E (energy by photon) | 9.3 × 10⁻¹⁹ J |
| Np (total number of photons | 1.1 × 10¹³ |
| generated by pulse) | |
| Ne (total number of electrons | 1.1 × 10⁸ |
| generated by pulse) | |
| Photoelectric I during the pulse | 4.28 mA |
| Charges emitted during the pulse | 17.1 picoCoulombs (pC) |
| Space charge in transit | 0.15 pC |

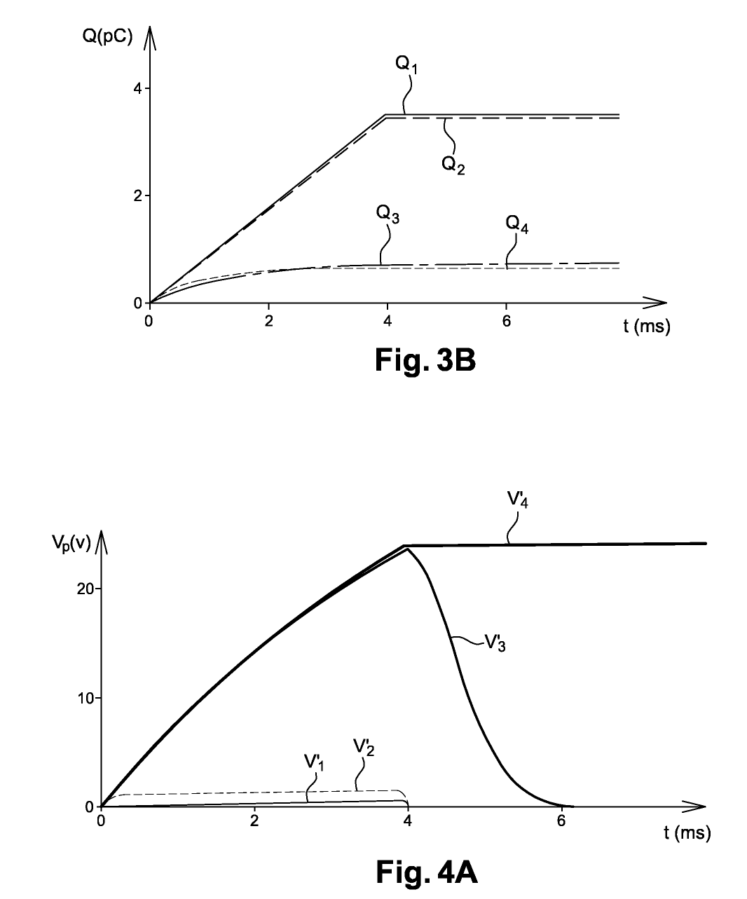

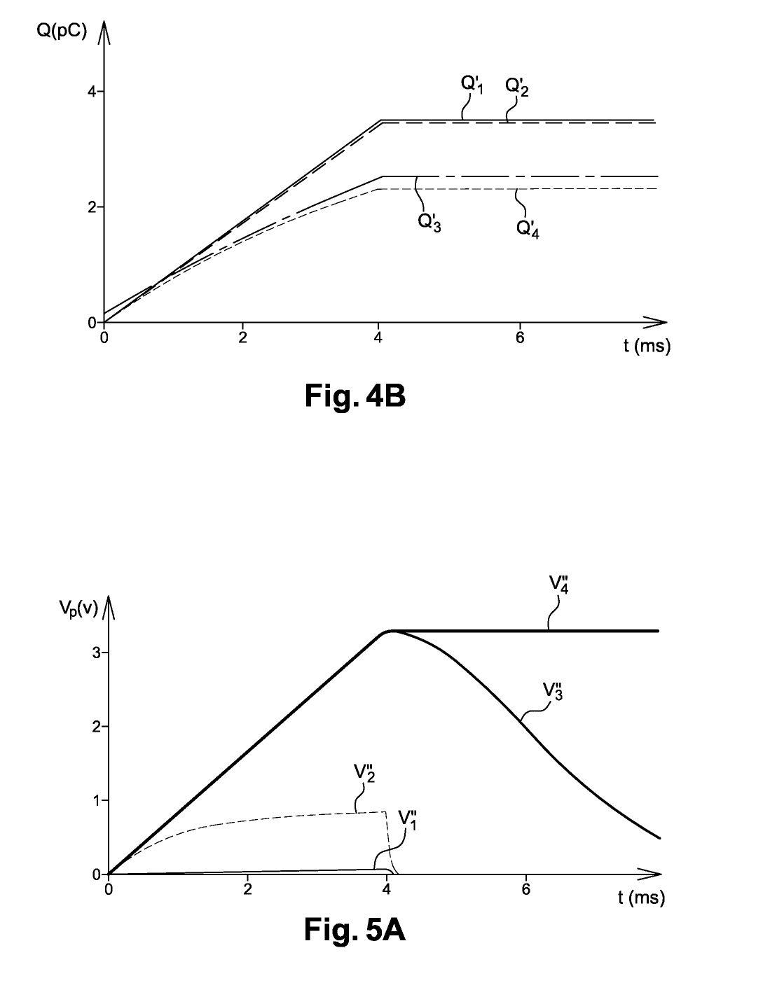

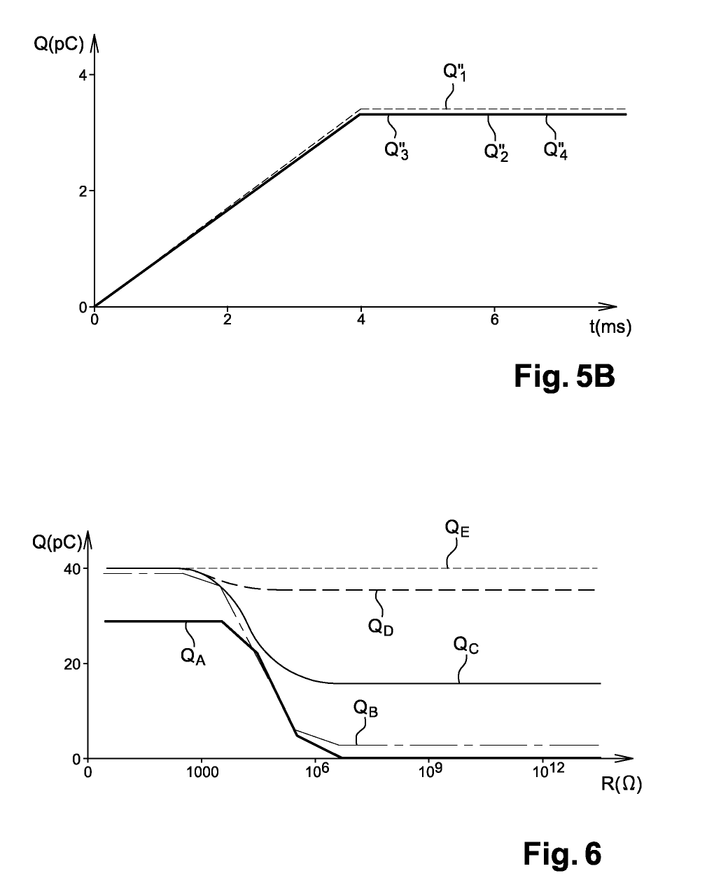

The curves V₁, V₂, V₃ and V₄ of FIG. 3A illustrate the evolution of the voltage Vp in Volts of the pad 4 after a laser shot according to time t in ns, for different values of resistances R₁=10 Ohms (Ω), R₂=1000Ω, R₃=1 MegaOhms (MΩ) and R₄=1000 GigaOhms (GΩ) of the path which capacitance is C=10 femtoFarads (fF), in the case of a simulation taking into account the parameters of Table 1. The curves V′₁, V′₂, V′₃ and V′₄ of FIG. 4A and the curves V″₁, V″₂, V″₃ and V″₄ of FIG. 5A illustrate the evolution of the voltage Vp for values of resistances R₁, R₂, R₃ and R₄ of the path identical to those mentioned above, but for capacitances C of the path equal to 100 fF in FIG. 4A and 1 pF in FIG. 5A, and according to the same parameters of Table 1. The curves Q₁, Q₂, Q₃ and Q₄ of FIG. 3B illustrate the evolution of the collected charge Q in pC according to time t in ns, for the different aforementioned values R₁, R₂, R₃ and R₄ of the path, which capacitance is C=10 fF, in the case of a simulation taking into account the parameters of Table 1. The curves Q′₁, Q′₂, Q′₃ and Q′₄ of FIG. 4B and the curves Q″₁, Q″₂, Q″₃ and Q″₄ of FIG. 5B illustrate the evolution of the collected charge Q for values of resistances R₁, R₂, R₃ and R₄ of the path identical to those mentioned above, but equal to 100 fF in FIG. 4B and 1 picoFarad (pF) in FIG. 5B.

For very high resistances (R=1000 GΩ), the voltage Vp increases and decreases very slowly with time. On the contrary, for very low resistances (R=10Ω), the voltage Vp hardly changes and remains near 0 V. For intermediary resistances (R=1000Ω or 1 MΩ), the voltage of the pad 4 increases to reach a maximum value around 4 ns, and progressively decreases, for the tested capacitance values. In all cases, the collected charge increases with time. This charge varies with resistance. In practice, the lower the resistance is, the more significant is the collected charge. The rise of potential during the shot explains the variation of the collected charge.

In FIG. 6, the curves Q_{A}, Q_{B}, Q_{C}, Q_{D} and Q_{E} illustrate the evolution of the charge Q collected by the collector in pC according to the resistance of the path in Ohms, for the following values of capacitances C of the path: 1 fF, 10 fF, 100 fF, 1 pF and 10 pF, respectively. As it is shown in this figure, the collected charge varies with the resistance of the path. The higher the resistance is, the lower is the collected charge. All the curves have a same profile in inverted S and consequently each curve has an inflection point. The lower the capacitance is, the lower is this inflection point.

Thus, if the quantity of charges collected by a collector and the capacitance of a path are known, it is possible to deduce therefrom the resistance of this path. This quantity of charges is the quantity of charges actually flowing through the paths of the test. The quantity of charges is directly measured and not simply evaluated from a current intensity which would have been integrated.

The same procedure can be applied to test the non-crossing paths.

In this case, as shown in FIG. 1B, the laser beam 6 is applied to a location of the non-crossing conducting path 3 which measure of resistance and/or capacitance is desired, and more specifically, to the end of the path formed by the metallic pad 4-1.

In order to measure the resistance and/or capacitance of the path 3, the metallic pad 4-2 is linked to an infinite source of electrons 11. This source of electrons 11 is for example arranged on the metallic pad 4-2 of the considered path, on the upper face of the substrate 1. The source is constituted by a microtip cathode, a carbon nanotube cathode or a second laser beam producing an inverse photoelectric effect. It is linked, according to the invention, to the second measuring device 12 and to the ground 13.

As in the case of FIG. 1A, when the beam 6 reaches the metallic pad 4-1, electrons are liberated by the pad, by photoelectric effect. These electrons are collected by the collector 9.

The measuring principle is therefore identical to the measuring principle of the crossing paths described above.

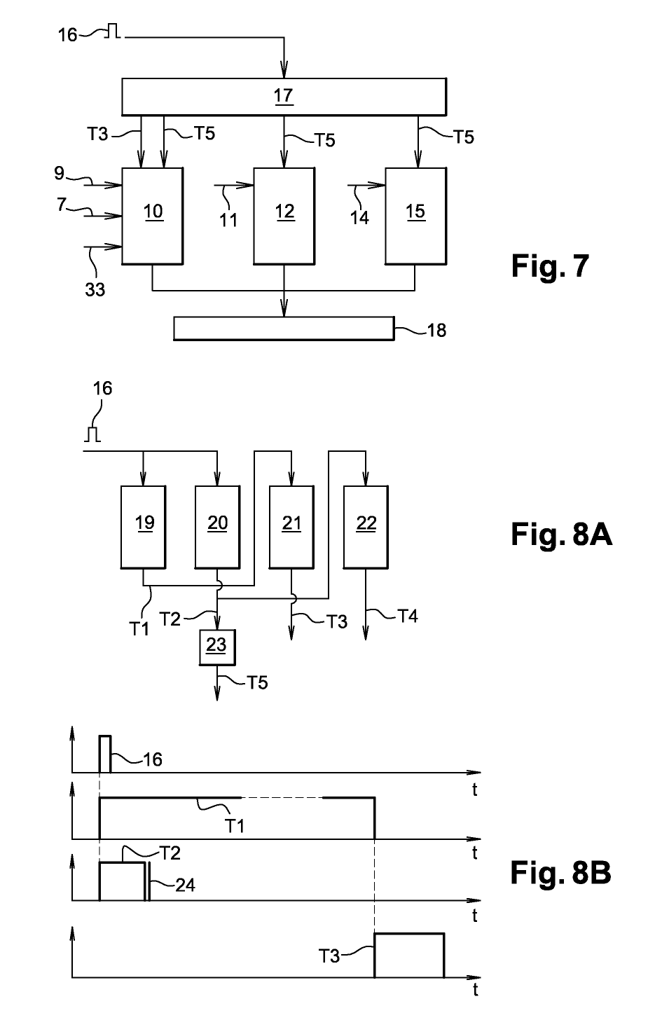

FIG. 7 is a diagram showing the different functional blocks of the measuring system according to the invention. As it is shown in this figure, this system comprises a device for generating a positive pulse 16 supplied by the power supply of the laser and which rising edge corresponds to the start of the firing of the laser shot. The system further comprises a unit 17 for resetting the measuring devices, the measuring device 12 located on the ground side, the measuring device 10 located on the collector side, the device 15 for measuring the energy of the laser and an acquisition card 18. The pulse 16 constitutes the input of the unit 17 for resetting the measuring devices. The output signal T5 of the unit 17 constitutes a reset signal applied to the input of the devices 10, 12 and 15. The output signal T3 of the unit 17 constitutes a signal for recharging the capacitances of the device 10. Other input signals of the devices 12, 10 and 15 come from the source of electrons 11, the collector 9, the generator 7 and the calorimeter 14. In addition, a command 34, which will be detailed with reference to FIG. 10, is applied to the input of the device 10. The output signals of the devices 12, 10 and 15 constitute input signals of the acquisition card 18.

In addition to the synchronous pulse 16 at the start of laser shot, the measuring system according to the invention implies generating square signals T1, T2, T3, T4 and T5 shown in FIG. 8A. This fig. is a functional diagram of the reset unit 17. T1 is a processing signal. T2 corresponds to a reset signal. T3 corresponds to a signal for recharging the capacitances C₁, C₂ and C₃ of the collector shown in FIG. 10, which will be defined hereinafter. T4 is a signal for calibrating the measuring system. According to a particular embodiment of the invention, the reset unit comprises four retarders 19, 20, 21 and 22 and means 23 for shaping the signal T2. The first retarder 19 generates the signal T1 from the synchronous pulse 16 at the start of laser shot. The second retarder 20 generates the signal T2 from the same pulse 16. The third retarder 21 generates the signal T3 from the signal T1. The fourth retarder 22 generates the signal T4 from the signal T2. The means 23 for shaping the signal T2 allow the signal T5 to be generated from the signal T2.

The synchronous pulse 16 at the start of laser shot is used to trigger the signals T1 and T2. The laser pulse 24 itself appears 210 pis after the rising edge of the pulse 16. The falling edge of T1 triggers the pulse T3 which will be used to recharge the capacitances C₁, C₂ and C₃ (FIG. 10). The falling edge of the signal T2 triggers the signal T4, which is used for the calibration of the measuring system. The signal T2 determines the duration of the reset of the device circuits arranged as a charge amplifier.

According to a particular embodiment of the measuring system shown in FIG. 8B, aiming in particular at using a flash-pumped laser, the rising edges of the signals T1 and T2 are synchronous with the rising edge of the synchronous pulse 16 at the start of flash laser. The rising edge of the signal T3 is synchronous with the falling edge of the signal T1. The duration of the signal T1 is equal to 1 ms. The duration of the signal T2 is of 190 μs. The duration of the signal T3 is of 200 μs.

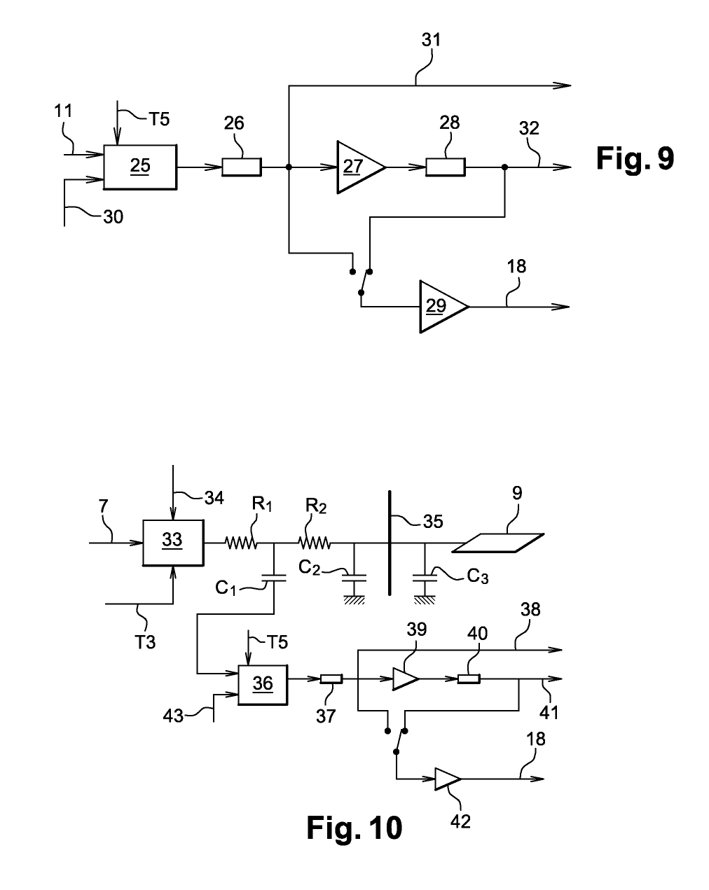

FIG. 9 is a functional diagram of the measuring device 12 of the system according to the invention, located on the ground side. This device 12 comprises a circuit 25 for measuring charges, a first filter 26, a gain 10 amplifier 27, a second filter 28 and a follower 29. At the input of the circuit 25, there are the reset signal T5, the input signal of the measure of charges, which comes from the source of electrons 11, and a drift correction signal 30. The output signal of the charge measuring circuit 25 is filtered by the first filter 26. The filtered signal 31 thus obtained corresponds to an output signal of the device 12. It can be amplified by the amplifier 27 and filtered again by the filter 28 to deliver an amplified signal 32. The follower 29 takes the output signal filtered by the second filter, the signal obtained at the output constituting an input of the acquisition card 18.

In practice, the device 12 comprises circuits, which first circuit is an operational amplifier, the amplifier being arranged as integrator. This amplifier is characterized by a very high input impedance Ze and by a very low input current ie. Another circuit allows the drift correction signal 30 to be injected into the “negative” input of the amplifier via a resistor in order to optimize the amplifier drift. If the integration capacitance is Ci, the sensitivity, expressed in Coulomb by Volt, is equal to Ci. This sensitivity has been chosen equal to Ci=10 pF. If Vs is the output voltage of the integrator after a shot, the quantity of electricity Qm measured is then Qm=Vs×10⁻¹¹ C. Measuring the quantity of electricity passing through the infinite source of electrons is performed by measuring the quantity of electricity conveyed by the charge (or discharge) current of a capacitance injected into an input of the operational amplifier, via a resistor.

FIG. 10 shows the measuring device 10 of the system according to the invention, located on the collector side 9. This device comprises a switch circuit 33 0/Vc of high impedance driven by a command 34, a vacuum tank, one wall of which is referenced 35 and, like the measuring device 12 on the ground side, a charge measuring circuit 36 to which are applied the signal T5 and a drift correction signal 43, a first filter 37, which delivers the signal 38 representing the charge measured by the collector 9, a gain 10 amplifier 39, a second filter 40 delivering an amplified signal 41 of a factor 10 and a follower 42. The operation of this device is similar to the operation of the measuring device 12. However, this circuit allows the quantity of charges collected by the collector 9 to be calculated. Indeed, the output voltage Vs is given by Vs=1/Ci×∫i×dt where ∫i×dt is the quantity of electricity Q collected at the input of the system. Therefore S=Q/V=Ci with Ci=10 pF. During the reset of the measuring circuits, if the command 34 is inactive, the collector 9 is taken to the voltage Vc by the circuit 33 through the resistors R₁ and R₂. During the laser pulse, the command 34 still being inactive, this circuit 33 insulates the collector 9 from the generator 7. The capacitances C1, C2, and C3 then deliver a current necessary to the measure. After the laser pulse, if the command 34 is inactive, the signal T3 recharges these capacitances C₁, C₂ and C₃ through the circuit 33. During the reset of the measuring circuits, if the command 34 is active, the collector 9 is put to the ground by the circuit 33 through the resistors R₁ and R₂. During the laser pulse, the command 34 still being active, this circuit 33 insulates the collector 9 from the generator 7. The capacitances C₁, C₂, and C₃ charge and then deliver a current necessary for the measure. After the laser pulse, if the command 34 is active, the signal T3 discharges these capacitances C₁, C₂ and C₃ again through the circuit 33. This configuration is used to reset the potential of the paths as described below.

Like the device 12, the device 10 comprises, in practice, circuits: a first circuit is an operational amplifier, the amplifier being arranged as an integrator. This amplifier is characterized by a very high input impedance Ze and by a very low input current ie. Another circuit allows the drift correction signal 43 to be injected into the “negative” input of the amplifier via a resistor in order to optimize the amplifier drift. If the integration capacitance is Ci, the sensitivity, expressed in Coulomb by Volt, is equal to Ci. In the case of the measure on the collector side, this sensitivity has been chosen equal to Ci=10⁻¹¹ F. If Vs is the output voltage of the integrator after a shot, the quantity of electricity Qm measured is then Qm=Vs×10⁻¹¹ C. The measure of the quantity of electricity passing through the collector is performed by measuring the quantity of electricity conveyed by the charge (or discharge) current of a capacitance injected into an input of the operational amplifier, via a resistor.

Eventually, according to embodiments of the invention, three measurements are taken for each path.

A first measurement aims at checking the continuity of the path. This first measurement normally goes with a measurement of the resistance of the path. This first measurement is implemented by using the photoelectric effect on one of the metallic pads of the path and a source of electrons on the other metallic pad. This measurement is based on the charge collected at each shot, where charge depends on the resistance of the path. The measurement is made by means of the measuring devices described above. The measurement of the resistance is made thanks to the knowledge of the feature of the photoelectric dipole and/or by using abacuses or calculation results giving the collected charge according to the resistance of the circuit. It is calibrated at each shot by the measure of the incident energy. For high values of resistances and/or capacitances of the paths, the measure is made following the temporal evolution of the charge collected from the measuring circuit. A simple way to access the value of the capacitance of the path is also to measure the charge collected when the path is completely charged after a shot. Indeed, if Q is this charge, V the voltage of the collector, and C the capacitance of the path, therefore C=Q/V. To be able to use this relationship, it is necessary to know the initial potential of the path, which is made by “resetting” the potential of the path. To that end, the collector is put to the ground during this preliminary phase which occurs just before the discharge shot(s), as explained above in relation with the command 34.

A second measurement aims at checking the primary insulation of the path in relation to all the other paths of the interconnection network, linked between them or to a same potential.

Eventually, a third measurement aims at sequentially checking the secondary insulation of the path compared to all the other paths individually considered. This third measurement is only made if the results of the second measure show that the path is not properly insulated in the interconnection network.

According to embodiments of the invention, a system for measuring the quantity of electricity is thus provided which precision is of about 10% and which dynamic can range from 10⁻¹³ to 10⁻⁸ Coulombs.

The invention is clearly not limited to the above-described embodiments.

In particular, for the implementation of embodiments of the invention, it is possible to use continuous lasers instead of a pulsed laser. It is even possible to use other means than the laser to induce a liberation of electrons at the level of the conducting paths, for example an electron, or ion gun. The electrons are therefore not liberated by photoelectric effect. Nevertheless, the measuring principle remains the same.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A method for testing or measuring electric elements, the method comprising:
applying a beam of particles to a first location of an electric element, electric charges are liberated under the effect of the application of the beam of particles;
collecting the liberated electric charges by a collector;
forming a dipole with the electric element;
measuring the collected quantity of electric charges; and
deducing the value of an electric feature of the electric elements from the measurement of the collected quantity of electric charges, taking the feature of the dipole into account or by using abacuses or results of calculations giving the collected charge according to the electric feature of the element, for a determined feature of the dipole.

2. The method according to claim 1, wherein the beam of particles is a laser beam.

3. The method according to claim 1, wherein the electric element is a conducting path either integrated to or deposited on an insulating substrate and comprises, at each of its two ends, a metallic pad.

4. The method according to claim 3, wherein the first location is a metallic pad.

5. The method according to claim 4, wherein the metallic pad is of C4 type.

6. The method according to claim 4, wherein the measure of the collected quantity of charges is ensured by a device for measuring collected charges comprising a capacitance, and the measure of the collected quantity of charges is made by measuring the charge of this capacitance.

7. The method according to claim 6, wherein a reset unit synchronizes the measure of the collected quantity of charges at the pulse of the beam of particles.

8. The method according to claim 6, wherein charges are injected into a second location of the electric element so as to compensate for the loss of charges extracted under the action of the beam of particles and wherein the quantity of charges injected by means of a device for measuring injected charges is measured.

9. The method according to claim 8, wherein the capacitance of the electric element is deduced from the quantity of injected charges.

10. The method according to claim 8, wherein the electric feature is the electric resistance or the capacitance of the electric element.

11. The method according to claim 9, wherein the electric feature is the electric continuity of the electric element or the electric insulation of the electric element in relation to another electric element.

12. A method for manufacturing an interconnection support or an electronic circuit arranged on an interconnection support, the interconnection support or the electronic circuit comprising electric elements, characterized in that it comprises a step of testing or measuring all or part of the electric elements of the interconnection support or of the electronic circuit implemented in accordance with the testing or measuring A method according to claim 1.

13. A system for testing or measuring electric elements, the system comprising:
a device for generating a beam of particles applied to a first location of an electric element; the application of the beam to the first location causing the liberation of electric charges;
a collector of the liberated electric charges, forming a dipole with the electric element;
a device for measuring the collected quantity of electric charges; and
a device for deducing, from the measurement of the collected quantity of electric charges, the value of an electric feature of the electric element, taking the feature of the dipole into account or by using abacuses or results of calculations giving the collected charge according to the electric feature of the element, for a determined feature of the dipole.

14. The system according to claim 13, comprising a device for generating a pulse preceding the start of the shot of the beam of particles, the pulse forming an input of a reset unit of the device for measuring the quantity of charges collected by the collector.

15. The system according to claim 14, further comprising a source allotted to an injection of charges into a second location of the electric element in order to compensate for the loss of charges extracted under the action of the beam of particles.

16. The system according to claim 15, further comprising a device for measuring the quantity of injected charges.

17. The system according to claim 16, further comprising a capacitance and wherein measuring the collected quantity of charges is performed by measuring the charge of the capacitance.

18. The system according to claim 17, being arranged for deducing an electric feature which is the electric resistance or the electric capacitance of the electric element.

19. The system according to claim 17, being arranged for deducing an electric feature which is the electric continuity of the electric element or the electric insulation of the element compared to another electric element.

20. The system according to claim 13, further comprising a source allotted to an injection of charges into a second location of the electric element in order to compensate for the loss of charges extracted under the action of the beam of particles.
